(19) United States
(12) Patent Application Publication
(10) Pub. No.: US 2024/0413143 A1
(43) Pub. Date: Dec. 12, 2024

(54) ELECTRONIC SYSTEM

(71) Applicant: PanelSemi Corporation, New Taipei City (TW)

(72) Inventor: Yu-Kai LIN, New Taipei City (TW)

(21) Appl. No.: 18/737,056

(22) Filed: Jun. 7, 2024

Related U.S. Application Data
(60) Provisional application No. 63/507,299, filed on Jun. 9, 2023.

(51) Int. Cl. H01L 25/16

(52) U.S. Cl. CPC H01L 25/167

(57) ABSTRACT

An electronic system includes a substrate and a control unit. The substrate includes at least one lighting unit and at least one driving unit corresponding to the lighting unit, and the driving unit includes a signal receiver. The control unit includes a signal providing unit for providing an optical signal to the signal receiver. The driving unit provides a current or a voltage to the corresponding lighting unit according to the optical signal received by the signal receiver from the signal providing unit of the control unit.

### CROSS REFERENCE TO RELATED APPLICATIONS

This Non-provisional application which claims priority under 35 U.S.C. § 119 (a) on Patent Application No(s). 63/507,299 filed in United States of America on Jun. 9, 2023, the entire contents of which are hereby incorporated by reference.

### BACKGROUND

### Technology Field

The disclosure relates to an electronic system.

### Description of Related Art

Transparent display, also known as see-through display, has a transparent substrate which provides an image content on the screen without obscuring objects in the back of the screen. The aperture ratio of a transparent display is one of the key factor affecting its transparency. In order to increase the aperture ratio of the transparent display, the distribution of circuits and electronic elements on the substrate needs to be carefully designed. In addition, the circuits can be made by transparent materials for increasing transparency. However, the design of the distribution of circuits and electronic elements becomes more difficult in the high-resolution transparent display.

### SUMMARY

One or more exemplary embodiments of this disclosure are to provide an electronic system.

An electronic system of this disclosure comprises a substrate and a control unit. The substrate comprises at least one lighting unit and at least one driving unit corresponding to the lighting unit. The lighting unit and the driving unit are disposed on one surface of the substrate. Further, the driving unit comprises a signal receiver. The control unit includes a signal providing unit to provide an optical signal to the signal receiver of the driving unit, and the driving unit provides an electrical signal to the corresponding lighting unit according to the optical signal received by the signal receiver from the signal providing unit of the control unit.

In one embodiment, the signal providing unit comprises a laser transmitter.

In one embodiment, the signal providing unit comprises a light source and a digital mirror device.

In one embodiment, a light spot projected by the optical signal providing unit covers at least a partial of the signal receiver of the driving unit.

In one embodiment, the substrate comprises plural lighting units and plural driving units corresponding to the lighting units respectively.

In one embodiment, the electrical signal includes a signal comprising at least one of a current and a voltage.

In one embodiment, the electronic system further includes a signal path, along which the optical signal travels, and the signal path is defined by at least one medium, and the medium includes air, an optical fiber, a waveguide, or a combination thereof.

In one embodiment, the driving unit comprises a plural of traces and a driving element, and the driving element and the signal receiver are electrically connected to the traces.

In one embodiment, the driving element comprises an integrated circuit, or a thin film driving element.

In one embodiment, the thin film driving element comprises a thin film transistor.

In one embodiment, the driving unit is in a micro-scaled level, ex. a micro integrated circuit.

In one embodiment, the driving element and the signal receiver are integrated into one module.

In one embodiment, the substrate comprises at least one patterned layer on at least one surface thereof and electrically connected to the lighting unit and the driving unit.

In one embodiment, the patterned layer comprises power lines.

In one embodiment, the power lines include a metallic material or a transparent conductive material.

In one embodiment, the transparent conductive material includes nano silver, indium zinc oxide (IZO), indium tin oxide (ITO), or a combination thereof.

In one embodiment, the substrate is a transparent substrate.

In one embodiment, a scan resolution of the laser transmitter is no less than a resolution of the driving unit on the substrate.

In one embodiment, a resolution of the digital mirror device is no less than a resolution of the driving unit on the substrate.

In one embodiment, the substrate is a film.

In one embodiment, the substrate is a flexible substrate.

In one embodiment, the substrate is a wind shield.

In one embodiment, the electrical signal is a current or a voltage for driving the lighting units.

In one embodiment, the lighting unit comprises at least one lighting element, and the lighting element comprises a self-emitting element.

In one embodiment, the self-emitting element comprises LED, mini LED, or micro LED.

In one embodiment, the lighting elements are driven by an active matrix (AM) method or a passive matrix (PM) method.

### BRIEF DESCRIPTION OF THE DRAWINGS

FIG. 1 is a schematic diagram of the present disclosure;

FIG. 2(A) and FIG. 2(B) are schematic diagrams showing the arrangement of the lighting element and the driving unit of the present disclosure;

FIG. 3(A) to FIG. 3(C) are schematic diagrams showing how the optical signal travels to project on the substrate of the present disclosure;

FIG. 4 is a schematic diagram showing a scan direction of the signal providing unit in one embodiment of the present disclosure; and

FIG. 5 is a schematic diagram showing a relation of the light spots projected on the substrate and the signal receiver in one embodiment of the present disclosure.

### DETAILED DESCRIPTION OF THE DISCLOSURE

The disclosure will become more fully understood from the detailed description and accompanying drawings, which are given for illustration only, and thus are not limitative of the present disclosure, wherein the same references relate to the same elements.

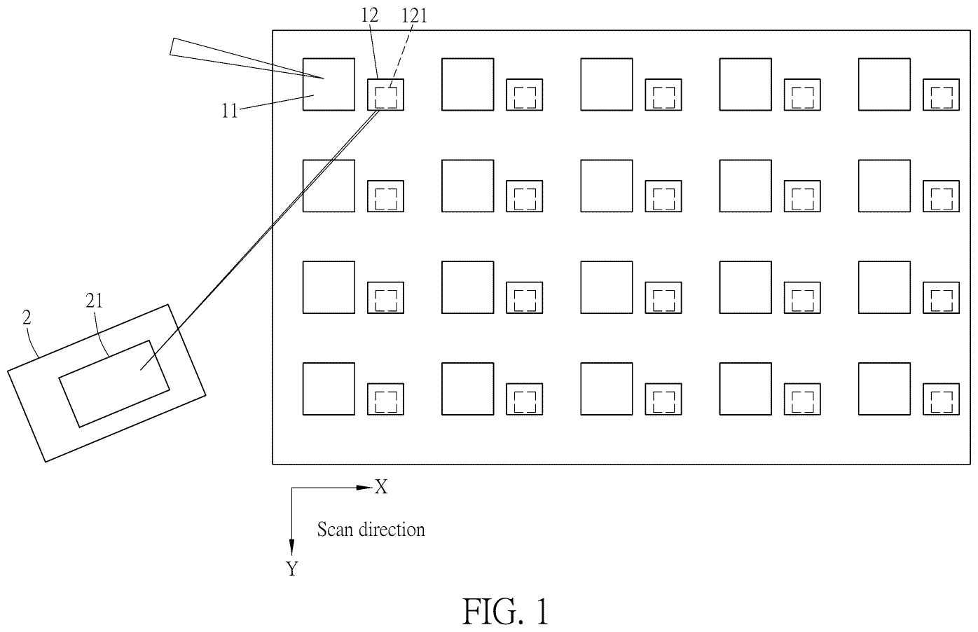

The present disclosure relates to an electronic system, which mainly comprises a substrate 1 and a control unit 2 as shown in FIG. 1. In this case, the control unit 2 is provided separately from the substrate 1 and is electrically disconnected to the substrate 1. However, the connection manner between the substrate 1 and the control unit 2 is not limited. In other cases, the control unit 2 can be electrically connected to the substrate 1 by wire(s).

The substrate 1 has at least one lighting unit 11 and at least one driving unit 12 corresponding to the lighting unit 11. The lighting unit 11 and the driving unit 12 are disposed on one surface of the substrate 1 in FIG. 1, but is not limited thereto. The lighting unit 11 comprises at least one lighting element, and the lighting element includes a self-emitting element. The self-emitting element includes light-emitting diode (LED), mini LED, or micro LED. In addition, the LED, mini LED, or micro LED can be a transparent LED. In FIG. 1, plural lighting units 11 and plural driving units 12 are provided on the substrate 1. The driving unit 12 comprises a signal receiver 121, a plural of traces and a driving element. The driving element comprises an integrated circuit, a thin film driving element or a combination thereof, but is not limited thereto. For example, the integrated element can be a micro-scaled integrated circuit. The thin film driving element includes a thin film transistor, especially a micro-scaled thin film transistor or micro-scaled thin film diode.

The substrate 1 can be a film or a transparent substrate. For example, the substrate 1 is a glass substrate, a polyimide (PI) substrate, or a combination thereof. In addition, the substrate 1 can also be a flexible thin substrate, such as a thin film. Furthermore, the substrate 1 can have a multi-layer structure.

The control unit 2 comprises a signal providing unit 21 and provides an optical signal to the signal receiver 112 of the driving unit 12, and then the driving unit 12 provides a current or a voltage to drive the corresponding lighting unit 11 according to the optical signal received. The signal providing unit 21 can be, for example but not limited to, a laser transmitter, or a source accompany with a digital mirror device. In some cases, the lighting elements 11 are driven by an active matrix (AM) method or a passive matrix (PM) method.

In FIG. 1, the lighting units 11 and the driving unit 12 are arranged in one-on-one manner, and one driving unit 12 only provides an electrical signal, e.g. a current or a voltage, to one lighting unit 11, but not limited thereto. In other embodiments, one driving unit 12 provide an electrical signal (a current or a voltage) to plural lighting units 11, or one lighting unit 11 can be driven by plural driving units 12.

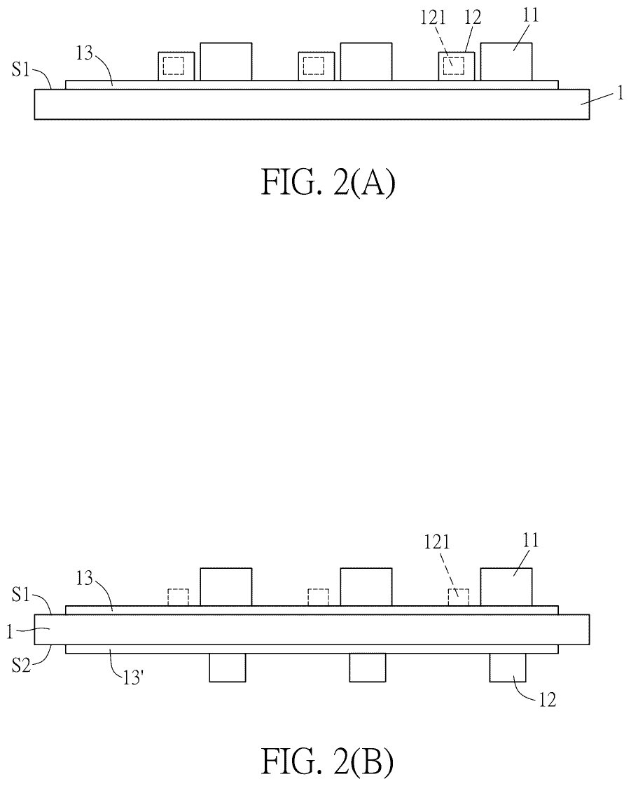

In the embodiment as shown in FIG. 1 and FIG. 2(A), the lighting unit 11 and the driving unit 12 are disposed on the same surface S1 of the substrate 1. In another embodiment as shown in FIG. 2(B), the lighting unit 11 is disposed on one surface S1 of the substrate 1, the driving unit 12 is disposed on another surface S2 of the substrate 1, and a perpendicular projection of the lighting unit 11 to the substrate 1 covers the corresponding driving unit 12. However, the signal receiver 121 of the driving unit 12 is disposed on the surface S1 where the lighting unit 11 is.

The substrate 1 can further include a patterned layer 13 on one surface S1 of the substrate 1, and the patterned layer 13 is electrically connected to the lighting units 11 and the driving units 12. In another embodiment as shown in FIG. 2(B), two patterned layers 13 and 13′ are respectively provided to two opposite surfaces of the substrate 1 for electrically connecting the lighting unit 11, the driving unit 12 and the signal receiver 121.

The patterned layer 13/13′ comprises power lines, and the power lines include a metallic material, a transparent conductive material or a combination thereof. For example, the transparent conductive material includes nano silver, indium zinc oxide (IZO), indium tin oxide (ITO) or a combination thereof.

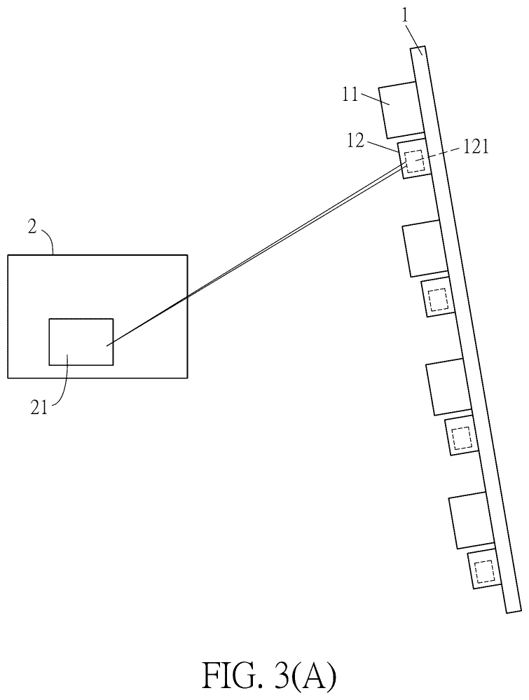

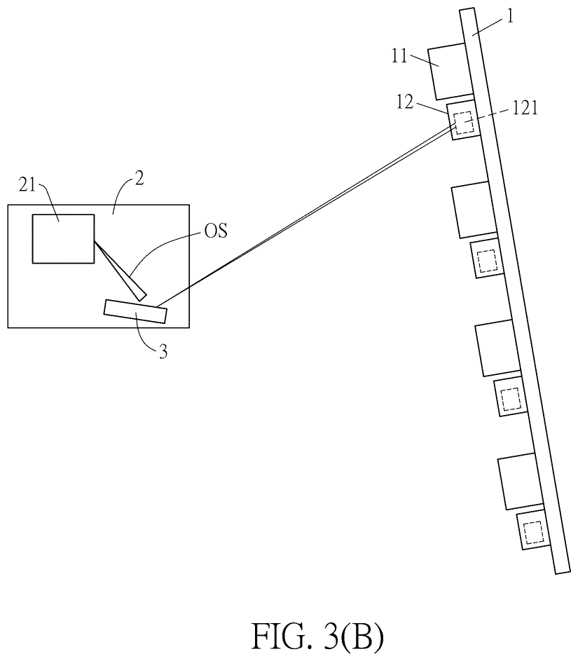

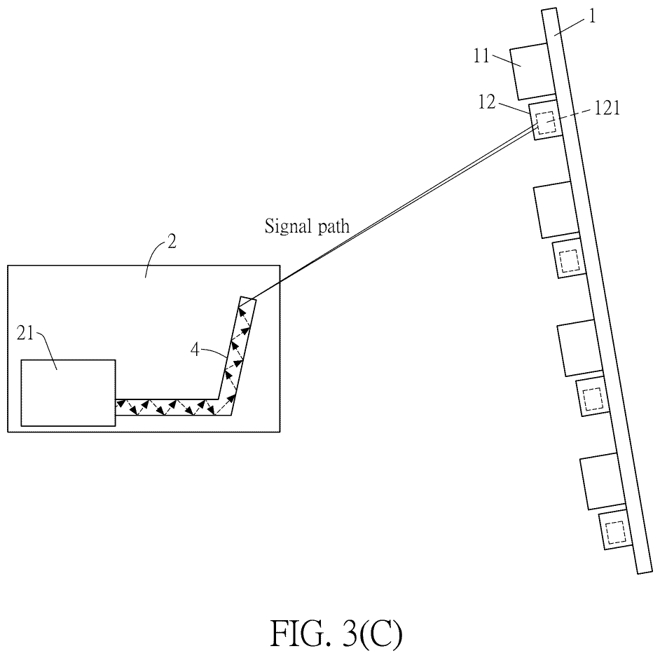

Referring to FIG. 3(A), the optical signal OS projected by the signal providing unit 21 is transmitted directly along a signal path to the signal receiver 121 without reflection or refraction. In another embodiment as shown in FIG. 3(B), the optical signal OS projected by the signal providing unit 21 is first transmitted to a reflector 3, for example, a mirror, and the optical signal OS is then being reflected and transmitted to the signal receiver 121. In another embodiment as shown in FIG. 3(C), the optical signal OS projected by the signal providing unit 21 is first transmitted by an optical fiber 4 and then transmitted to the signal receiver 121. In addition, the optical signal OS projected by the signal providing unit 21 can be also transmitted by a wave guide, or transmitted by a combination of air, the optical fiber, and the waveguide.

In one embodiment, the signal providing unit 21 of the control unit 2 provides the optical signal to the driving units 12 along a pre-determined direction and forming at least one light spot 5 on the substrate 1. In addition, the light spot 5 projected on the substrate 1 covers at least partial of the signal receiver 121 of the driving unit 12 for signal transmission. For example, the light spot 5 projecting on the signal receiver 121 can be designed as a rod shape or other shapes having a larger area than a single signal receiver 121 for covering the signal receiver 121 of the driving unit 12 as possible. This design can prevent projecting inaccuracy caused by external vibration.

In one embodiment, the driving unit 12 comprises a plurality of traces and a driving element, and the driving element and the signal receiver 121 are electrically connected to the traces. The driving element comprises an integrated circuit, or a thin film driving element, and the thin film driving element comprises a thin film transistor. The driving unit 12 can be a micro-scaled level, ex. a micro integrated circuit. In addition, the driving element and the signal receiver can be separated from each other, or integrated into one module.

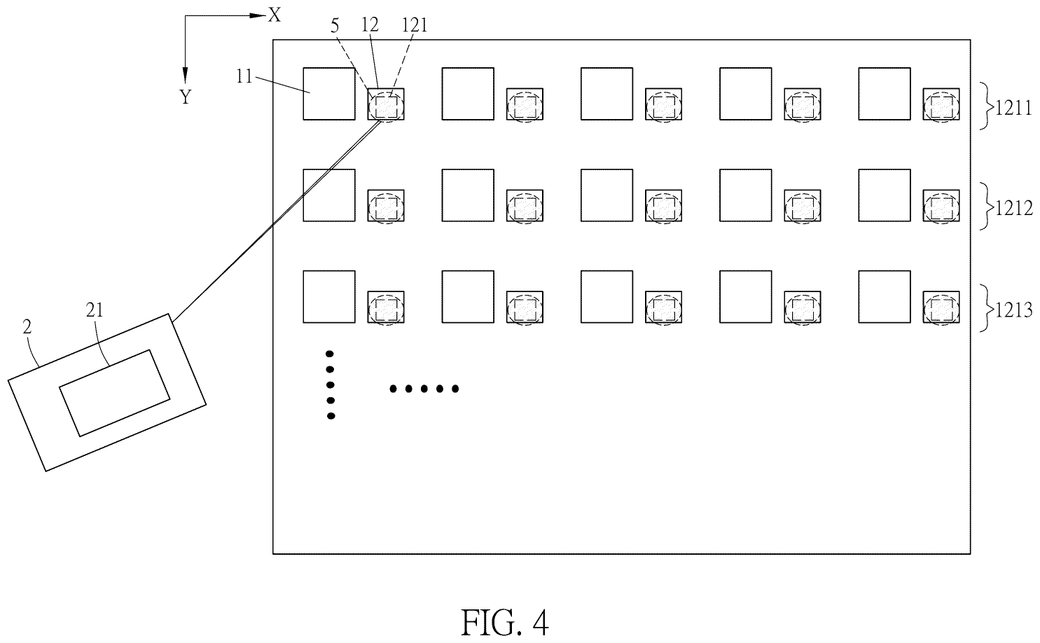

As shown in FIG. 4, the signal providing unit 21 projects plural light spots 5 on a first row 1211 of the driving units 12 of the substrate along a first direction X first, and then the signal providing unit 21 sequentially projects plural light spots 5 on a second row 1212, a third row 1213, and a fourth row of the driving units 12 along a second direction Y, and so on. However, the scan direction of the signal providing unit 21 on the substrate 1 is not limited thereto.

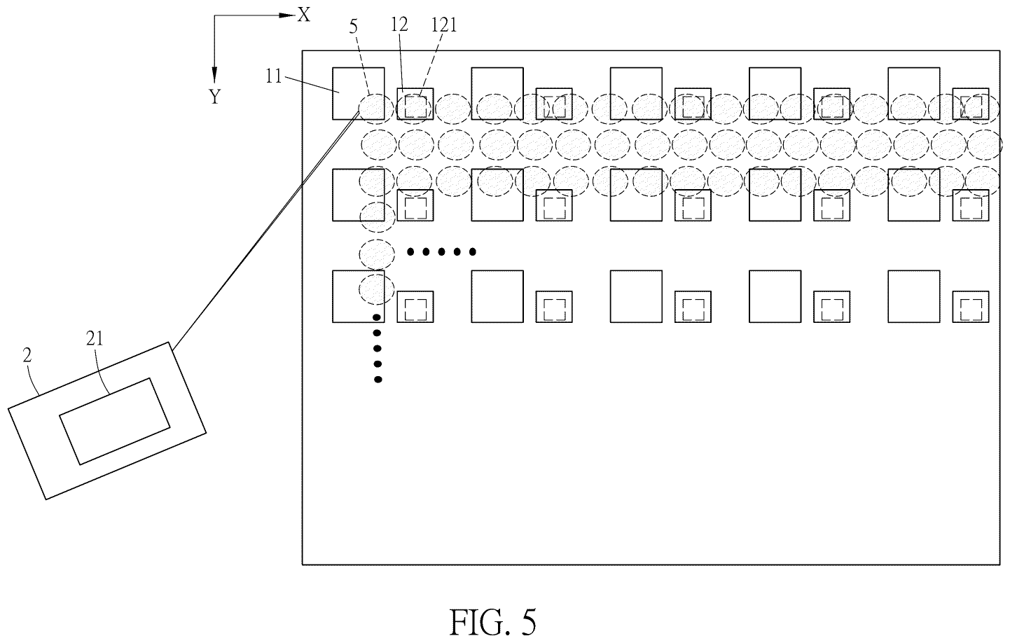

In one embodiment shown in FIG. 5, the density of the light spot 5 projected on the substrate 1 is greater than the density of the signal receivers 121 on the substrate 1. In this embodiment, a distance between two adjacent light spots 5 in at least one direction is smaller than the distance between two adjacent signal receivers 121 in the same direction. Preferably, the distance between two adjacent light spots 5 in any direction is smaller than the distance between two adjacent signal receivers 121 in the same direction. This design can avoid formation of moiré pattern when the present disclosure is working. In other words, a scan resolution of the laser source or a resolution of the digital mirror device or both are no less than a resolution of the driving unit on the substrate.

In one embodiment, the signal providing unit is a laser scanner, the optical signal provided is a light beam, and the light beam scans the driving units on the substrate sequentially. Furthermore, the signal providing unit can be a low-powered laser scanner, and the driving unit is just served as an amplifier to amplify the optical signal from the signal providing unit in this case, and an energy waste of the signal providing unit is prevented.

In another embodiment, the signal providing unit is a light source accompany with a digital micro-mirror device (DMD), and the optical signal provided is laid out in a matrix which can be received by multiple signal receivers at the same time.

The electronic system of the present disclosure can be applied to transportation such as a vehicle or an aircraft and served as a head up display. In one embodiment, the electronic system is served as a head up display for a vehicle. The windshield of the vehicle is considered as the substrate in the present disclosure and is provided with a transparent patterned layer in its surface, and the lighting unit and the driving unit are directly disposed on the substrate (windshield) and are electrically connected to the transparent patterned layer.

In one embodiment, the control unit of the present disclosure can be separated from and electrically disconnect to the substrate (windshield). In other words, the control unit is installed in an area different from the substrate. When the substrate is served as a windshield, the control unit is installed in an area other than the windshield. The control unit provides an optical signal from the signal providing unit and the optical signal is transmitted to the signal receiver of the driving unit on the substrate (windshield). In this embodiment, the signal providing unit is a laser scanner, for example a laser scanner with low power which provides a laser bean as the optical signal. After receiving the laser beam by the signal receiver of the driving unit, the driving unit covert the optical signal to a driving signal according to the characteristics of the laser beam, such as an intensity, a ratio, or a type of the laser beam. Then, the driving unit provides a current or a voltage to the lighting unit according to the driving signal for driving the lighting unit. The lighting unit is then illuminated according to the current or the voltage.

In another embodiment, the lighting unit and the driving unit are directly disposed on a transparent flexible substrate, such as a transparent flexible film, and the transparent flexible substrate is than installed on the windshield, rear window or side window(s) of a vehicle.

In one embodiment, the substrate is only provided with lighting units, driving units and traces, and the image data are transmitted by the control unit. In other words, the data lines, scan lines and other elements for transmission image data arranged on the substrate are significantly reduced. Therefore, the transparent area of the substrate are increased as possible so as to increase aperture ratio of the substrate. Furthermore, since the traces arranged on the substrate are decreased, radial distortion such as barrel distortion of the image provided thereof can be ameliorated.

Accordingly, the electronic system of the present disclosure provides a transparent substrate served as a display panel and a control unit for providing image data by transmission an optical signal to the substrate. The substrate of the present disclosure is provided with less circuits since the data signal is transmitted by optical signal form the control unit so as to increase the aperture ratio of the substrate. In addition, the lighting element in this disclosure can be self-emitting element which has better brightness. Therefore, the present disclosure has better transparency and brightness than a traditional transparent display.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. An electronic system, comprising:
a substrate comprising at least one lighting unit and at least one driving unit corresponding to the lighting unit, wherein the driving unit comprises a signal receiver; and
a control unit including a signal providing unit for providing an optical signal to the signal receiver;
wherein the driving unit provides an electrical signal to the corresponding lighting unit according to the optical signal received by the signal receiver from the signal providing unit of the control unit.

2. The electronic system as claimed in claim 1, wherein the signal providing unit comprises a laser transmitter.

3. The electronic system as claimed in claim 1, wherein the signal providing unit comprises a light source and a digital mirror device.

4. The electronic system as claimed in claim 1, wherein a light spot projected by the signal providing unit covers at least partial of the signal receiver of the driving unit.

5. The electronic system as claimed in claim 1, wherein the substrate comprises plural lighting units and plural driving units corresponding to the lighting units respectively.

6. The electronic system as claimed in claim 1, wherein the driving unit comprises a plurality of traces and a driving element, and the driving element and the signal receiver are electrically connected to the traces.

7. The electronic system as claimed in claim 6, wherein the driving element comprises an integrated circuit or a thin film driving element.

8. The electronic system as claimed in claim 7, wherein the thin film driving element comprises a thin film transistor.

9. The electronic system as claimed in claim 1, wherein the substrate comprises a patterned layer electrically connected to the lighting unit and the driving unit.

10. The electronic system as claimed in claim 9, wherein the patterned layer comprises power lines.

11. The electronic system as claimed in claim 10, wherein the power lines include a metallic material or a transparent conductive material or a combination thereof.

12. The electronic system as claimed in claim 1, wherein the substrate is a transparent substrate.

13. The electronic system as claimed in claim 2, wherein a scan resolution of the laser transmitter is no less than a resolution of the driving unit on the substrate.

14. The electronic system as claimed in claim 3, wherein a resolution of the digital mirror device is no less than a resolution of the driving unit on the substrate.

15. The electronic system as claimed in claim 1, wherein the substrate is a wind shield.

16. The electronic system as claimed in claim 1, wherein the lighting unit comprises at least one lighting element, and the lighting element comprises a self-emitting element.

17. The electronic system as claimed in claim 16, wherein the self-emitting element comprises a LED, a mini-LED, or a micro-LED.

18. The electronic system as claimed in claim 6, wherein the driving element and the signal receiver are integrated into one module.
